(19) United States
(12) Patent Application Publication
(10) Pub. No.: US 2004/0266115 A1
(43) Pub. Date: Dec. 30, 2004

(54) Method of making a gate electrode on a semiconductor device

(76) Inventors: Bor-Wen Chan, Hsin chu (TW); Fang-Cheng Chen, Hsin chu (TW)

Correspondence Address: DUANE MORRIS, LLP, IP DEPARTMENT, ONE LIBERTY PLACE, PHILADELPHIA, PA, 19103-7396, US

(21) Appl. No.: 10/603,361

(22) Filed: Jun. 25, 2003

(51) Int. Cl. H01L 21/336

(52) U.S. Cl. 438/284; 438/283

(57) ABSTRACT

A semiconductor device (1) has a fin (2) and a multiple gate electrode (3) over the fin (2), the multiple gate electrode (3) being a layer of gate electrode material with a substantially planar surface (13b) to support a patterned mask (14a), the mask (14a) having a uniform thickness and a planar surface controlling the patterning dimensions of the patterned mask (14a).

### FIELD OF THE INVENTION

The present invention relates to a multiple gate electrode on a semiconductor device, and a method of making a multiple gate electrode on a semiconductor device, wherein the method controls the dimensions of the multiple gate electrode.

### BACKGROUND

MOSFETs, metal-oxide-silicon field effect transistors, have been reduced in size to improve speed, performance, circuit density and cost per unit. However, a MOSFET of reduced size causes the source and drain to interact with the channel, and to influence the channel electrical potential. The channel is an insulating portion of a substrate that is between the source and drain of the transistor. A multiple gate is a transistor gate that wraps around, or circumscribes the channel, which improves the capacitive coupling between the multiple gate and the channel. Further, the multiple gate increases the gate control of the channel electrical potential, and suppresses short channel effects. Further, the multiple gate has enabled size reduction of a transistor to well into a sub 30 nm size.

A fin transistor is constructed with a source, drain and channel on projecting fin. Multiple gates of the fin transistor extends on more than one side of the fin. The multiple gates are formed from a multiple gate electrode material, according to the following process. A continuous layer of gate electrode material is deposited over a fin that has a thin coating of a gate dielectric, followed by applying a layer of a photoresist mask material. A lithographic mask having an opaque pattern is applied to the layer of mask material, which outlines the final dimensions of a patterned mask. With the lithographic mask on the mask material, the mask material is photo exposed, followed by etching the photo exposed mask material by an anisotropic etchant. The anisotropic etchant etches rapidly in one direction, i.e., vertically, to remove each photo exposed portion of the mask material, thus forming a patterned mask on the layer of gate electrode material.

It is important that the mask material have a flat surface, to position the mask material and the lithographic pattern at a focus of photo exposure. However, the mask material is thinner where the mask material extends across the height of the projecting fin. Consequently, the etchant, first, vertically etches through the thinner portion of the mask material until reaching the gate electrode material on the top surface of the fin. Then, the etchant will begin to etch in a lateral direction, along the top of the gate electrode material, while the etchant continues to etch in a vertical direction elsewhere through thicker portions of the mask material. Thus, the thinner portion of the patterned mask, over the top of the fin, will be laterally etched with inaccurate width dimensions.

With the patterned mask on the layer of gate electrode material, the gate electrode material is removed by an anisotropic etchant. The patterned mask covers portions of the gate electrode material to stop lateral etching thereof. Thus, a discrete multiple gate electrode is formed by etching. However, the multiple gate electrode will have an inaccurate length due to the inaccurate width dimensions of the patterned mask. The gate length dimension is a critical dimension that affects the capacitive coupling between the multiple gate and the channel, the gate control of the channel electrical potential, and the suppression of short channel effects.

U.S. Pat. No. 6,492,212 discloses chemical mechanical planarization, CMP, performed after a patterned mask has been formed, and after a discrete gate electrode has been formed. The patent discloses CMP of a discrete gate electrode, which reduces both step height and surface roughness of the gate electrode. However, polishing by CMP polishes an overall surface that includes, not only the discrete gate electrode, but also other structural features and different materials that are adjacent to the discrete gate electrode. A discrete gate electrode, being a discrete element, is difficult to planarize by CMP without causing CMP dishing of the discrete gate electrode, and CMP erosion of other features and materials adjacent to the discrete gate electrode. In addition, the patent does not disclose a method of making a multiple gate electrode, which controls the dimensions of the multiple gate electrode.

### SUMMARY OF THE INVENTION

The invention resides in a method of making a multiple gate electrode on a semiconductor device, by applying a layer of gate electrode material over a semiconductor device, followed by planarizing the layer of gate electrode material prior to patterning the gate electrode material to form a discrete multiple gate electrode. The planarized layer of gate dielectric material has a smooth, planar surface finish, and is accurately patterned to form a multiple gate electrode of precisely controlled dimensions. The invention further relates to a semiconductor device having a multiple gate electrode on more than one side of a semiconductor fin, the multiple gate electrode having a substantially planar surface extending over the fin; and a patterned mask on the planar surface of the multiple gate electrode, the patterned mask having a substantially uniform thickness and a substantially planar surface.

### BRIEF DESCRIPTION OF THE DRAWINGS

FIG. 1 is an isometric view of a portion of a transistor during manufacture thereof.

FIG. 2 is an isometric view of a portion of a transistor during manufacture thereof.

FIG. 3, is a side view of semiconductor fins on a substrate.

FIG. 4 is a side view of semiconductor fins with gate dielectric thereon.

FIG. 5 is a side view of semiconductor fins with a layer of gate electrode material.

FIG. 6 is a side view of planarizing a layer of gate electrode material.

FIG. 7 is an isometric view of a mask material and a lithographic mask.

FIG. 8 is an isometric view of a patterned mask on gate electrode material.

FIG. 9 is an isometric view of a multiple gate on a semiconductor fin.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,” “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

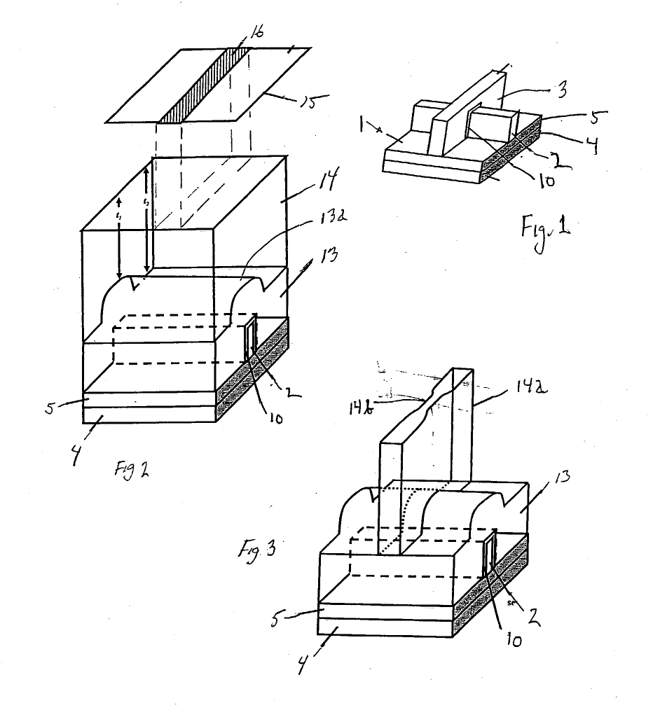

FIG. 1 discloses a semiconductor device (1), for example, a transistor having a projecting fin (2) that comprises an elemental semiconductor material, including but not limited to, silicon or germanium, an alloy semiconductor material, for example, silicon-germanium, or a compound semiconductor material, for example, gallium arsenide or indium phosphide.

A multiple gate electrode (3) is formed from a gate electrode material (13) that comprises, a conducting material, including but not limited to, polycrystalline-silicon, poly-Si, poly-crystalline silicon-germanium, poly-SiGe, and other conducting materials. The thickness of the gate electrode material is in a range of 500 Angstroms to 4000 Angstroms. In an embodiment of the invention, the gate electrode material is preferred to be undoped poly-Si with a thickness of about 2000 Angstroms.

A gate dielectric (10) covers the surfaces of the fin (2), and is a thin layer of silicon dioxide or silicon oxynitride with a thickness in the range of 3 Angstroms to 100 Angstroms, for example, and preferably 10 Angstroms or less. Further, for example, the gate dielectric (10) comprises a dielectric material with a high permittivity, for example a permittivity larger than 8, which comprises a high-k dielectric material, including but not limited to, lanthalum oxide La₂O₃, aluminum oxide Al₂O₃, hafnium oxide HfO₂, hafnium oxynitride HfON, zirconium oxide, ZrO₂, or zirconium oxynitride ZrON, and combinations thereof with a thickness providing an equivalent isolation as does a thickness range of 3 to 100 Angstroms of silicon oxide.

FIG. 2 discloses a process for making a multiple gate electrode (3) on more than one side of a semiconductor fin (2). A layer of a gate electrode material (13) is deposited as a layer covering a projecting semiconductor fin (2) that has been covered by a thin film of gate dielectric (10). The fin (2) projects from an insulation covered wafer (4), preferably of silicon. Multiple fins (2) on the insulation covered wafer (4) are similarly covered by the gate dielectric (10) and by the gate electrode material (13). The layer of gate electrode material (13) is deposited with a substantially uniform thickness. However, the layer of gate electrode material (13) has a step height difference where it covers and conforms to the increased step height of each semiconductor fin (2).

A common feature of a multiple gate transistor is that the sidewall surfaces of the semiconductor fin (2) conduct a significant amount of source to drain current when the transistor (1) switches to a conducting state. Desirably, the larger the fin height, the more current can be conducted by the transistor (1), without having the transistor (1) consume more linear area on a semiconductor wafer (4). For example, a fin height h for a double gate transistor (1) has an effective width that is equivalent to a planar transistor width of 2h. A triple gate transistor (1), having a fin height h and a width w, has an effective width that is equivalent to a planar transistor width of (2h+w). However, the fin height contributes to manufacturing difficulties that result in manufacture of multiple gate electrode (3) with dimensional inaccuracies.

With continued reference to FIG. 2, a process for making a multiple gate electrode (3) will now be discussed. A layer of a photoresist mask material (14) is applied over the layer of gate electrode material (13). A lithographic mask (15) having an opaque pattern (16) is applied to the mask material (14), which outlines the final dimensions of the multiple gate (9). The mask material (14) is photo exposed, followed by etching by an anisotropic etchant, which etches rapidly in one direction, i.e., vertically, to remove photo exposed portions of the mask material (14) from the layer of gate electrode material (13).

It is important that the mask material (14) have a flat surface, to position the lithographic pattern (16) at the focus of photo exposure. However, beneath the mask material (14), the layer of gate electrode material (13) has an increased step height (13a), caused by the layer of gate electrode material (13) covering and extending over the increased step height of the projecting semiconductor fin (2). The increased step height (13a) inaccurately positions the lithographic pattern (16) at the focus of photo exposure, causing irregular patterning of the mask material (14). Thus, to compensate for an increased step height (13a) of the layer of gate electrode material (13), the mask material (14) has a thinner thickness, where the mask material (14) extends across the increased step height (13a). However, the thinner thickness of the mask material (14) contributes to irregular patterning of the mask material (14).

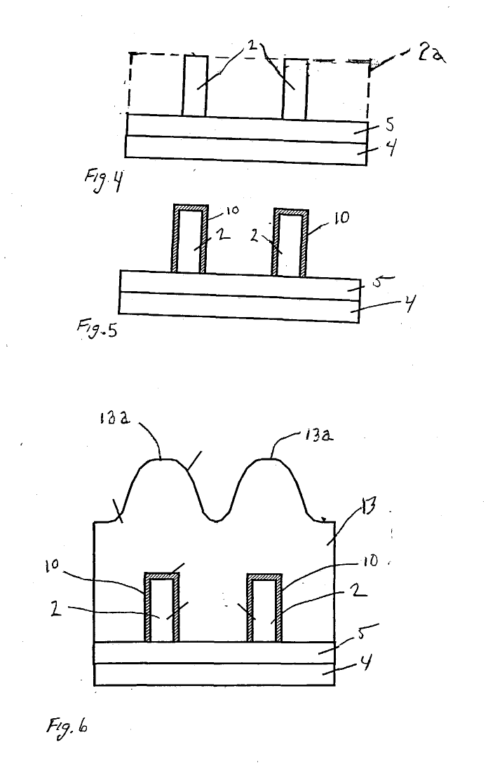

With reference to FIG. 3, the process will be further discussed. During etching to pattern the mask material (14), the etchant, which has finished removing thinner portions of the mask material (14), will begin to etch in a lateral direction, while the etchant continues to etch vertically through thicker portions of the mask material (14). Thus, sections of the patterned mask (14a) will have an irregular lateral width (14b) that constitute inaccuracies in the patterned mask (14a). Subsequently, excess gate electrode material (13) is removed by an anisotropic etchant, while the patterned mask covers portions of the gate electrode material (13) to stop lateral etching.

A patterned gate, or gate electrode (3), results from etching. However the patterned gate will have an inaccurate length, in a direction, source to gate to drain, due to inaccurate etching, as allowed by inaccuracies in the width of the patterned mask (14a). The gate length is a critical dimension that affects the capacitive coupling between the gate (3) and the channel (8), and the gate control of the channel electrical potential, and the suppression of short channel effects.

With reference to FIG. 4 a method of making the multiple gate electrode on the fin (2) will be discussed. A semiconductor layer (2a), a precursor to making one or more fins (2), is applied to cover a substrate, for example, a substrate constructed with a planarized, interlayer (5) of an insulator that covers an underlying substrate layer (4), for example, a silicon wafer or another planarized interlayer.

The semiconductor layer (2a) for manufacture of the fins (2) comprises, silicon, an alloy semiconductor, such as, silicon-germanium, or a compound semiconductor, such as, gallium arsenide or indium phosphide, having a thickness in the range of 200 Angstroms to 5000 Angstroms, by way of example only. Further, by way of example, the semiconductor layer (2a) is silicon, to provide fins (2) of silicon.

The interlayer (5) comprises a dielectric or insulator, for example, silicon oxide or silicon nitride, having a thickness in the range of 100 to 2000 Angstroms, by way of example only.

According to an embodiment, a semiconductor layer (2a) of silicon is deposited on an interlayer (5) of silicon oxide, in turn, which has been deposited on the substrate (4) of silicon.

With further reference to FIG. 4, one or more, multiple fins (2) are formed by depositing a mask, not shown, comprising, photoresist or silicon oxide resist over the semiconductor layer (2a), followed by patterning the mask with openings to expose portions of the semiconductor layer (2a) for removal by etching. Subsequently, etching the exposed portions of the semiconductor layer (2a), of silicon, for example, constructs multiple projecting fins (2). The mask is removed to reveal the fins (2). For example, the height of each fin (2) is in the range of about 300-700 Angstroms, and can exceed 900 Angstroms.

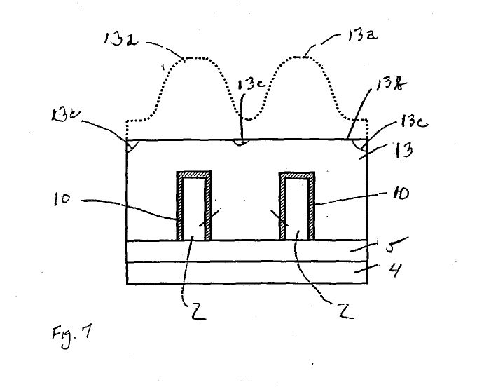

With reference to FIG. 5, a thin layer of material, by which each gate dielectric (10) is formed, is formed to cover the fins (2), for example, by, thermal oxidation, chemical vapor deposition, sputtering, or any known process of coating. Either selective coating is performed, or alternatively, complete coating followed by selective etching is performed, to cover solely the projecting fins (2) with the gate dielectric (10). The thickness of the gate dielectric (10) on the top side of each fin (2) can be different than that on the other sides of the same fin (2). For example, according to an embodiment of the present invention, the thickness on the top side is less than 20 Angstroms. According to the invention, the total step height, the sum of the height of the fin (2), plus, the thickness of the gate dielectric can exceed 900 Angstroms.

With reference to FIG. 6, a layer of conducting gate electrode material (13) is applied or formed to cover the previously covered fins (2), by a process, including but not limited to, chemical vapor deposition. The material (13) for each gate electrode (3) is undoped at this stage of the process. Alternatively, it may be lightly doped, without either requiring or eliminating a further doping process according to the invention. The gate electrode material (13) is sufficiently thick to provide a gate thickness covering each of the sides of each fin (2). Accordingly, the gate electrode material (13) tends to fill in the spaces between adjacent fins (2). Further, the gate electrode material (13), when applied, has a nonplanar top surface. The top surface has a raised step height (13 a), due to the height of each projecting fin (2) underlying the gate electrode material (13). The step height difference in the top surface of the gate electrode material (13), prior to the invention, has caused the various problems previously discussed herein with reference to FIGS. 2 and 3.

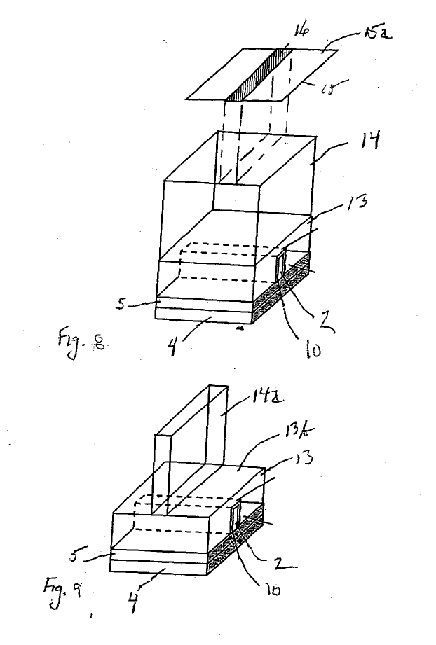

FIG. 7 discloses an embodiment of a process according to the present invention, which results in a semiconductor device having a multiple gate electrode (3) of precisely controlled dimensions, particularly, the length dimension.

With reference to FIG. 7, the step height differences on the surface of the layer of gate electrode material (13) are removed, for example, by CMP. A smooth, planar polished surface is provided by performing CMP. Further, the thickness of the layer of gate electrode material (13) is reduced to a precise final thickness of the gate electrode (3) on the top side of each fin (2). For example, the root means square, RMS, roughness of the planarized gate electrode material (13) is preferably less than 100 Angstroms.

FIG. 7 further discloses that the surface (13b) of the gate electrode material (13) is planarized, for example, by performing CMP. CMP is performed by polishing the gate electrode material (13) with a polishing pad and a fluid polishing composition that chemically reacts with the surface of the gate electrode material (13), while polishing with the polishing pad removes products of chemical reaction that go into solution with the fluid polishing composition. On the surface being polished by CMP, the portions having the greatest step height (13a) will be removed by CMP faster than the portions having the least step height. A known occurrence of dishing (13c) appears as recesses in the final polished surface (13b). Dishing (13c) occurs at the portions of the gate electrode material (13) having the least initial step height. Advantageously, the dishing is located in a portion of the gate dielectric material (13) that will be removed by etching to form the discrete multiple gate electrode (3).

According to the invention, planarization is performed on the continuous, uninterrupted layer of gate electrode material (13) prior to application of a patterned mask (14a) thereon, and prior to patterning the gate electrode material (13) so as to form a discrete multiple gate electrode (3) on each fin (2). Planarization of the layer of continuous gate electrode material (13) provides a continuous planarized surface (13b) on the layer of gate electrode material (13). Thus, the invention avoids planarizing of discrete gate electrodes, and avoids the problems caused thereby. Planarizing discrete gate electrodes causes dishing of the discrete gate electrodes and round off of edges thereof. Further, planarizing discrete gate electrodes causes erosion of other structural features and other materials, which are adjacent to the discrete gate electrodes during planarization.

FIG. 8 discloses the application of a mask material (14) onto the planarized gate electrode material (13). A flat lithographic mask (15) has a transparent region (15a) and an opaque pattern (16) overlying the mask material (14). Because the mask material (14) is on a continuous planarized surface (13b) of the layer of gate electrode material (13), the mask material (14) itself is substantially uniformly planar, and has a uniform thickness. Advantageously, the mask material (14) is positioned precisely at a focus of photo exposure, due to the uniform planarity of the mask material (14). The mask material (14) is patterned by photo exposure of each portion of the mask material (14) that is exposed by the transparent region (15a) of the lithographic mask (15). The lithographic mask (15) accurately transfers its opaque pattern (16) of precise dimensions to the mask material (14).

With reference to FIG. 8, a patterned mask (14a) on the layer of gate electrode material (13) is formed by anisotropic etching of the mask material (14) to remove each photo exposed portion of the mask material (14). Because the mask material (14) is substantially uniform in thickness, anisotropic etching of the mask material (14) is substantially vertical through the entire thickness of the mask material (14), and without significant lateral etching, which provides a patterned mask (14a) of precisely controlled dimensions. Particularly, the width of the patterned mask (14a) is uniform, without the irregularities caused by a patterned mask (14a) of varying thickness, as described with reference to FIGS. 2 and 3. Further, the patterned mask (14a) has substantially vertical walls that precisely outline the length of the multiple gate electrode (3) that will be formed by etching with the patterned mask (14a) in place on the dielectric material (13).

With reference to FIG. 9, the multiple gate electrode (3) on a semiconductor fin (2) is formed by anisotropic etching of the gate electrode material (13) to remove each portion of the gate electrode material (13) that is uncovered by the patterned mask. Preferably, dry plasma etching is performed. Because the patterned mask (14a) has uniform width dimensions, and substantially vertical walls, such precisely controlled dimensions of the patterned mask become transferred to the gate electrode material (13), forming the multiple gate electrode (3) of precisely controlled dimensions. Particularly, the length of the multiple gate electrode (3) is precisely controlled, without the irregularities of a gate electrode as described with reference to FIGS. 2 and 3. Further, the multiple gate electrode (3) will have substantially vertical walls formed by etching.

Further, each portion of the gate dielectric (10) that is uncovered by the multiple gate electrode (3) is removed, by etching, for example. According to an embodiment of the present invention, etching of the gate electrode material (13), by a selective etchant, stops on the gate dielectric (10), and is followed by removal of each exposed portion of the gate dielectric (10) by wet or dry etching by a selective etchant. According to another embodiment of the invention, both the gate electrode material (13) and the gate dielectric (10) are removed by the same etching process, preferably a dry plasma etching process. As disclose by FIG. 8, both, the multiple gate electrode (3), and the underlying gate dielectric (10) extend on more than one side of the semiconductor fin (2). The channel (8), or channel region, is the portion of the semiconductor fin (2) that is covered successively by the gate dielectric (10) and the gate electrode (3).

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A method of making a multiple gate electrode on a semiconductor device, comprising the steps of:
coating a layer of gate electrode material over a semiconductor device that has been previously coated with a thin film of gate dielectric; and
planarizing the layer of gate electrode material to a substantially planar surface prior to patterning the gate electrode material to form a discrete multiple gate electrode on the semiconductor device.

2. The method of claim 1, further comprising the steps of:
applying a photoresist mask of substantially uniform thickness on the planar top surface of the planarized gate electrode material;
patterning the photoresist mask to cover a corresponding pattern of the discrete multiple gate electrode; and
etching the gate electrode material that is uncovered by the photoresist mask to form the discrete multiple gate electrode.

3. The method of claim 1, further comprising the step of:
conforming the layer of gate electrode material with a step height increase corresponding to an increased step height of the semiconductor device.

3. The method of claim 1 wherein, the semiconductor device comprises a silicon fin.

4. The method of claim 1 wherein, the semiconductor device comprises a fin of silicon and germanium.

5. The method of claim 1, further comprising the steps of:
applying a photoresist mask of substantially uniform thickness on the planar top surface of the planarized gate electrode material, the mask comprising photoresist and a mask material selected from the group comprising, silicon nitride, silicon oxynitride, silicon oxide and photo resist, or combinations thereof;
patterning the photoresist mask to cover a corresponding pattern of the multiple gate electrode; and
etching the gate electrode material that is uncovered by the photoresist mask to form the discrete multiple gate electrode.

6. The method of claim 1, further comprising the steps of:
applying a photoresist mask of substantially uniform thickness on the planar top surface of the planarized gate electrode material;
patterning the photoresist mask to cover a corresponding pattern of the multiple gate electrode; and
plasma etching the gate electrode material that is uncovered by the photoresist mask to form the patterned multiple gate electrode.

7. The method as recited in claim 1, further comprising the step of: applying a mask over the planarized surface, wherein the mask is of substantially uniform thickness for accurate patterning thereof.

8. The method of claim 1 wherein, the gate dielectric comprises silicon oxide.

9. The method of claim 1 wherein, the gate dielectric comprises silicon oxynitride.

10. The method of claim 1 wherein, the gate dielectric comprises a high permittivity material.

11. The method of claim 1 wherein, the gate dielectric comprises a material having a permittivity greater than 5.

12. The method of claim 1 wherein, the gate dielectric comprises a thickness in the range of 3 and 100 Angstroms.

13. The method of claim 1 wherein, the multiple gate electrode comprises polycrystalline silicon.

14. The method of claim 1 wherein, the multiple gate electrode comprises a conductive material.

15. The method of claim 1 wherein, the multiple gate electrode comprises a metal material.

16. A semiconductor device having a multiple gate electrode, comprising:
the semiconductor device having a projecting fin;
a multiple gate electrode on more than one side of the fin, the multiple gate electrode having a substantially planar surface extending over the fin; and
a patterned mask on the planar surface of the multiple gate electrode, the patterned mask having a substantially uniform thickness and a substantially planar surface.

17. The semiconductor device of claim 16 wherein, the multiple gate electrode is a portion of a layer of gate electrode material having a planarized surface, and the planarized surface includes the planar surface of the multiple gate electrode.
